(19) United States
(12) Patent Application Publication
(10) Pub. No.: US 2010/0020494 A1
(43) Pub. Date: Jan. 28, 2010

(54) HEAT DISSIPATION DEVICE

(75) Inventors: QING-LEI GUO, Shenzhen City (CN); SHOU-LI ZHU, Shenzhen City (CN); YI-CHYNG FANG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 12/328,778

(22) Filed: Dec. 5, 2008

(30) Foreign Application Priority Data
Jul. 28, 2008 (CN) 200810303124.1

(51) Int. Cl. H05K 7/20

(52) U.S. Cl. 361/696; 361/697

(57) ABSTRACT

A heat dissipation device includes a heat sink and a fan. The heat sink includes a first fin assembly and two second fin assemblies located on two opposite sides of the first fin assembly respectively. The first fin assembly includes a plurality of parallel first fins arranged side by side. A first airflow channel is formed between each two neighboring first fins and communicates with a top side of the heat sink. Each of the second fin assemblies includes a plurality of parallel second fins. A second airflow channel is formed between each two neighboring second fins and communicates with the top side of the heat sink. The first fins are perpendicular to the second fins with the first airflow channels and the second airflow channels communicating with four sides of the heat sink, respectively.

### BACKGROUND

1. Technical Field

The disclosure relates to heat dissipation devices, and particularly to a heat dissipation device having a plurality of fins forming improved air guiding channels.

2. Description of related art

Modern electronic components in a computer can operate at very high speed. The faster an electronic component operates the more heat it generates. Excessive heat can make the electronic component unstable, or even cause damage to the electronic component or associated electronic components in the computer. Therefore, heat must be removed efficiently to ensure normal operation. Typically, a heat dissipation device attaches to the electronic component for heat dissipation.

A conventional heat dissipation device includes a flat base mounted on a main electronic component, a plurality of parallel fins extending upwardly from the base, and a fan mounted on the fins. An airflow channel is formed between each two neighboring fins. During operation of the heat dissipation device, the fan creates an airflow towards the fins, and the airflow is finally guided out of the fins along the airflow channels towards other electronic components located at two opposite sides of the heat sink to take Page 1 of 20 heat away therefrom.

Since the fins are vertical flat plates parallel to each other, the airflow guided by the fins can only flow towards two opposite sides of the heat sink; certain electronic components located on the other two opposite sides of the heat sink can not cooled by the airflow, which restricts the utilization efficiency of the airflow.

It is thus desirable to provide a heat dissipation device which can overcome the described limitations.

### SUMMARY

The present invention relates to a heat dissipation device. According to a preferred embodiment of the present invention, the heat dissipation device includes a heat sink and a fan. The heat sink includes a first fin assembly and two second fin assemblies located on two opposite sides of the first fin assembly respectively. The first fin assembly includes a plurality of parallel first fins arranged side by side. A first airflow channel is formed between each two neighboring first fins. Each first airflow channel is communicated with a top side of the heat sink. Each of the second fin assemblies includes a plurality of parallel second fins arranged side by side. A second airflow channel is formed between each two neighboring second fins. Each second airflow channel is communicated with the top side of the heat sink. The first fins are perpendicular to the second fins with the first airflow channels and the second airflow channels communicating with four sides of the heat sink, respectively. The fan is mounted the top side of the heat sink for generating an airflow towards the first airflow channels and the second airflow channels. The airflow flows to the four sides of the heat sink via the first and second airflow channels.

Other advantages and novel features of the present invention will become more apparent from the following detailed description of preferred embodiment when taken in conjunction with the accompanying drawings.

### BRIEF DESCRIPTION OF THE DRAWINGS

FIG. 1 is a perspective, exploded view a heat dissipation device according to an exemplary embodiment and an electronic component.

FIG. 2 is a perspective, exploded view of a heat sink of the heat dissipation device of FIG. 1.

FIG. 3 is a view similar to FIG. 2, but viewed from a bottom aspect.

### DETAILED DESCRIPTION OF THE EMBODIMENT

Reference will now be made to the drawing figures to describe the present embodiment in detail.

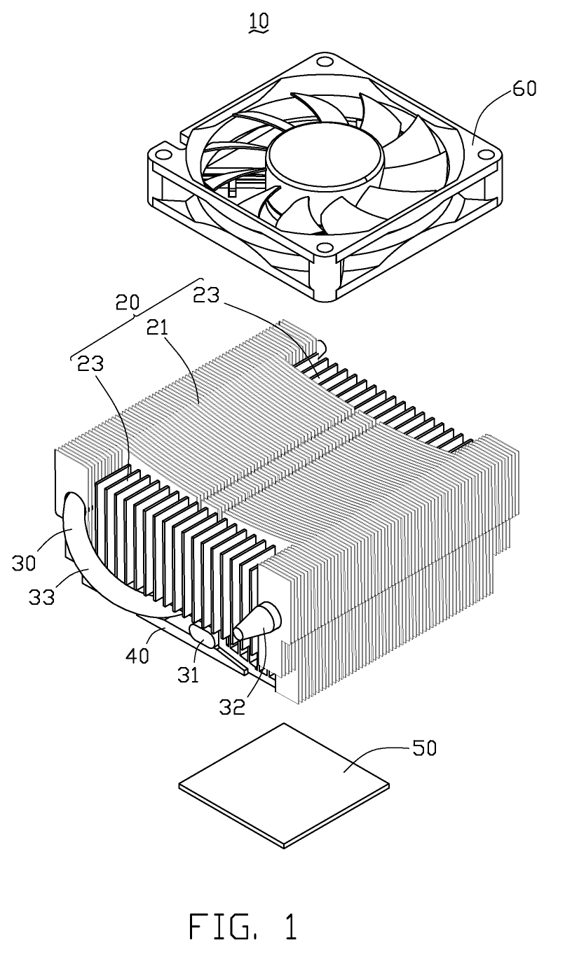

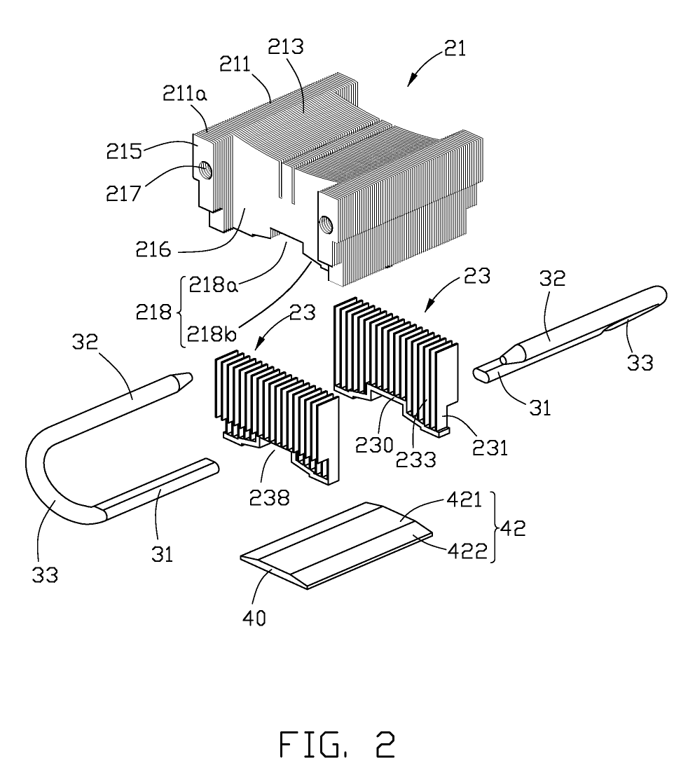

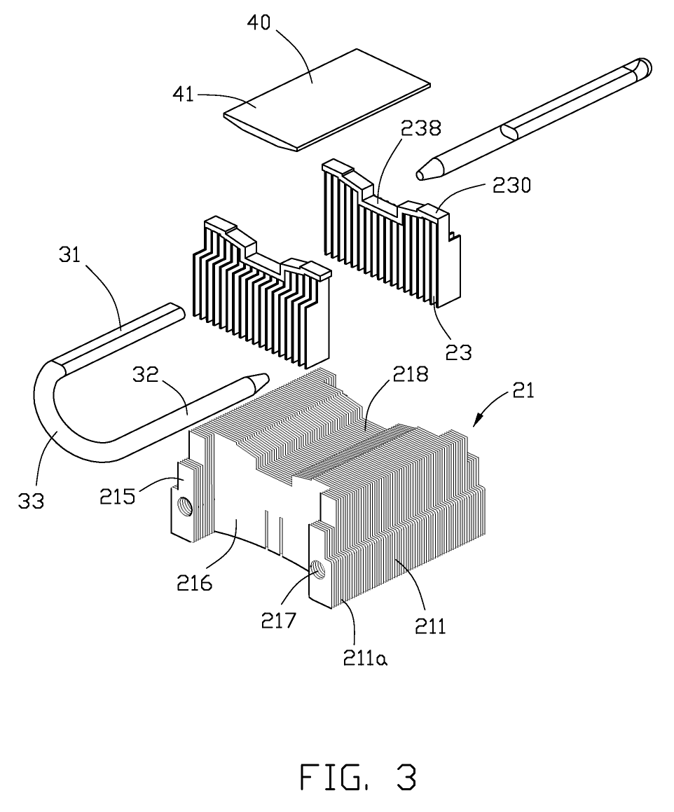

Referring to FIG. 1 and FIG. 2, a heat dissipation device 10 includes a heat sink 20, a fan 60 mounted on a top side of the heat sink 20, and a heat-absorbing block 40 mounted on a bottom side of the heat sink 20. The heat sink 20 has two heat pipes 30 extending therethrough. The heat-absorbing block 40 is used for engaging with an electronic component 50, which is a main electronic component such as a CPU of a mother board (not shown). The heat-absorbing block 40 has a bottom surface 41 (FIG. 3) contacting with the electronic component 50 and a top surface 42 supporting the heat sink 20 with the heat pipes 30 thereon. The top surface 42 includes a flat middle portion 421 and two slant portions 422 extending downwardly and outwardly from left and right sides of the flat middle portion 421, respectively. Heat generated by the electronic component 50 is absorbed by the heat-absorbing block 40 and dissipated into air through the heat sink 20.

Each of the heat pipes 30 is about U-shaped. Each of the heat pipes 30 includes a condenser section 32, an evaporator section 31 and an adiabatic section 33 interconnected between the condenser section 32 and the evaporator section 31. The evaporator sections 31 of the heat pipes 30 are parallel to each other, and the condenser sections 32 of the heat pipes 30 are parallel to each other. The condenser section 32 has a round section while the evaporator section 31 has a flat configuration with flat top and bottom surfaces.

The heat sink 20 in whole has a substantially rectangular configuration. The heat sink 20 includes a first fin assembly 21, and two second fin assemblies 23 arranged at two opposite sides of the first fin assembly 21, respectively.

The first fin assembly 21 includes a plurality of parallel first fins 211 arranged side by side and a plurality of parallel heat dissipation vanes 211a arranged side by side and located on two opposite sides (i.e., front and rear sides) of the first fins 211. Each of the heat dissipation vanes 211a has a size smaller than the first fin 211. In this embodiment, each of the first fins 211 and the heat dissipation vanes 211a extends along a left-to-right direction of the heat sink 20. The first fins 211 are located on a middle portion of the first fin assembly 21. The heat dissipation vanes 211a are located on the front side and the rear side of the first fin assembly 21, respectively. The heat dissipation vanes 211a on the front side of the first fin assembly 21 are grouped into two spaced units on a left end and a right end of the heat sink 20, respectively, thus to form two horny portions 215 on the front side of the first fin assembly 21. A first receiving room 216 is defined between the two horny portions 215 on the front side of the first fin assembly 21. Similarly, the heat dissipation vanes 211a on the rear side of the first fin assembly 21 are grouped into two units on the left end and the right end of the heat sink 20, respectively, thus to form another two horny portions 215 on the rear side of the first fin assembly 21, and a second receiving room 216 is defined between the another two horny portions 215 on the rear side of the first fin assembly 21. Accordingly, a top plan view of the first fin assembly 21 is generally H-shaped. The first fins 211 and the heat dissipation vanes 211a are parallel to each other, and a first airflow channel 213 is formed between each two neighboring first fins 211 and heat dissipation vanes 211a.

Two through holes 217 are defined in the left end and the right end of the first fin assembly 21, respectively. Each of the through holes 217 has a diameter slightly larger than the diameter of each of the condenser sections 31 of the heat pipes 30. Each of the through holes 217 is for receiving the condenser section 31 of a corresponding heat pipe 30 therein. A groove 218 is defined in a middle portion of a bottom side of the first fins 211. The groove 218 includes a lower portion 218b diverging downwardly, for receiving the heat-absorbing block 40 therein and a rectangular upper portion 218a. The upper portion 218a of the groove 218 has a width substantially the same as the flat middle portion 421 of the block 40, and slightly larger than a sum of the widths of the evaporator sections 32 of the heat pipes 30. A minimum distance between each of the through holes 217 and the groove 218 substantially equals to the distance between the condenser section 31 and the evaporator section 32 of each heat pipe 30. A depth of the upper portion 218a of the groove 218 is substantially equal to a thickness of the evaporation section 31 of the heat pipe 30; thus, the evaporation sections 31 of the heat pipes 30 can be sandwiched closely between the bottom side of the first fins 211 and flat middle portion 421 of the heat-absorbing block 40.

The second fin assemblies 23 have substantially the same configuration to each other, and are received in the first and the second receiving rooms 216 of the first fin assembly 21, respectively. Each of the second fin assemblies 23 includes a base 230 and a plurality of second fins 231 extending perpendicularly and upwardly from a top surface of the base 230. The second fins 231 are parallel to each other and arranged side by side. The base 230 is an elongated plate with a protruding section formed on a middle portion thereof. A concave hollow 238 corresponding to the protruding section is thus formed on a bottom surface of the base 230. The concave hollow 238 has a size and shape substantially equals to the groove 218 of the first fins 211. The concave hollow 238 and the groove 218 communicate with each other after the first fin assembly 21 and the second assemblies 23 are assembled together. The concave hollows 238 and the groove 218 cooperatively form a receiving channel on the bottom side of the heat sink 20 for receiving the evaporator sections 31 of the heat pipes 30 side by side. The second fins 231 are spaced from each other. Each of the second fins 231 extends along a front-to-rear direction of the heat sink 20. A second airflow channel 233 is formed between each two neighboring second fins 231. That is, each of the second fins 231 is perpendicular to the first fins 211 and the heat dissipation vanes 211a of the first fin assembly 21, and each of the second airflow channels 233 is perpendicular to each of the first airflow channels 213 of the first fin assembly 21.

During assembly of the heat sink 20, the second fin assemblies 23 are received in the first and the second receiving rooms 216 of the first fin assembly 21, respectively, and the heat pipes 30 each interconnects a corresponding second fin assembly 23 with the first fin assembly 21 for connecting the second fin assemblies 23 and the first fin assembly 21 together. The condenser sections 32 of the heat pipes 30 insert into the through holes 217 formed at the left side and the right side of the first fin assembly 21 respectively. The evaporator sections 32 embedded into the concave hollows 238 and the groove 218 are in thermal engagement with the bottom sides of the first fin assembly 21 and the second fin assemblies 23 by soldering. The adiabatic sections 33 extend outwardly from the condenser sections 32 towards the evaporator sections 31 around portions of the second fin assemblies 23. Accordingly, the heat sink 20 is assembled with the heat pipes 30 extending therethrough.

The second fins 231 of the second fin assemblies 23 contact with outmost ones of the first fins 211, which are located at a frontmost side and a rearmost side of the first fin assembly 21 respectively. Each of the first airflow channels 213 communicates the left side and right side of the heat sink 20. Each of the second airflow channels 233 of the second fin assembly 23, which is located at the front side of the first fin assembly 21, communicates the front side of the heat sink 20. Each of the second airflow channels 233 of the second fin assembly 23, which is located at the rear side of the first fin assembly 21, communicates the rear side of the heat sink 20. Each of the first airflow channels 213 and the second airflow channels 233 communicates the top side of the heat sink 20.

The heat-absorbing block 40 is installed on the electronic component 50 with the bottom surface 41 thereof attaching to the electronic component 50; the heat sink 20 with the heat pipes 30 is mounted on the heat-absorbing block 40; and the fan 60 is mounted on the top side of the heat sink 20. The bottom side of the first fin assembly 21 and the second fin assemblies 23 and the evaporator sections 31 of the heat pipes 30 are in thermal contact with the top surface of the heat-absorbing block 40. The fan 60 is configured for generating an airflow towards and through the first airflow channels 213 and the second airflow channels 233. Therefore, the heat dissipation device 10 is assembled together and mounted the electronic component 50, and the first airflow channels 213 and the second airflow channels 233 communicate with the front side, the rear side, the left side and the right side of the heat sink 20 with the top side of the heat sink 20.

During operation of the heat dissipation device 10, the heat-absorbing block 40 absorbs heat from the electronic component 50; the heat is spread on the first fins 211, the heat dissipation vanes 21 la and the second fins 231 via the bottom side of the heat sink 20 and the heat pipes 30; and finally the heat is dissipated to ambient air via the first fins 211, the heat dissipation vanes 211a and the second fins 231. The fan 60 rotates and produces an airflow towards the heat sink 20 in spiral cylindrical pattern. The airflow impels the heat absorbed by the first, second fins 211, 231 and the heat dissipation vanes 211a into the ambient air. Since the first fins 211, the heat dissipation vanes 211a and the second fins 231 are oriented towards all sides, i.e., the front side, the rear side, the left side and the right side, of the heat sink 20 respectively, the airflow can enter easily into the first airflow channels 213 of the first fin assembly 21 and the second airflow channels 233 of the second fin assemblies 23, respectively. Thus, the efficiency of the forced convention between the heat sink 20 and the airflow is increased. Moreover, the airflow can be guided out of the first airflow channels 211 and the second airflow channels 233 towards other electronic components located beside all of the four sides of the heat sink 20, i.e., the front side, the rear side, the left side and the right side, of the heat sink 20 respectively to take heat away therefrom, thereby improving the utilization efficiency of the airflow produced by the fan 60.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device comprising:
a heat sink comprising a first fin assembly and two second fin assemblies located on two opposite sides of the first fin assembly respectively, the first fin assembly comprising a plurality of parallel first fins arranged side by side, a first airflow channel being formed between each two neighboring first fins, the first airflow channel communicated with a top side of the heat sink, each of the second fin assemblies comprising a plurality of parallel second fins, a second airflow channel being formed between each two neighboring second fins, the second airflow channel communicated with the top side of the heat sink, the first fins being perpendicular to the second fins with the first airflow channels and the second airflow channels communicated with four sides of the heat sink respectively; and
a fan mounted on the top side of the heat sink for generating an airflow through the first airflow channels and the second airflow channels.

2. The heat dissipation device as described in claim 1, wherein the first fin assembly further comprises a plurality of heat dissipation vanes each having a smaller size than the first fin, the heat dissipation vanes arranged on four corners of the first fin assembly to form four horny portions on the four corners correspondingly, two receiving rooms being defined in the two opposite side of the first fin assembly respectively, each of the receiving rooms being defined between two corresponding horny portions.

3. The heat dissipation device as described in claim 1, further comprising two heat pipes, each of the heat pipes comprising a condenser section and an evaporation section, two through holes being defined in the first fin assembly for receiving the condenser sections of the heat pipes therein respectively, the evaporation sections thermally contacting with bottom sides of the first and second fin assemblies.

4. The heat dissipation device as described in claim 3, wherein a groove is defined in the bottom sides of the first and second fin assemblies for receiving the evaporation sections of the heat pipes therein side by side.

5. The heat dissipation device as described in claim 3, wherein the evaporation sections are parallel to each other and the condenser sections of the heat pipes are parallel to each other, the evaporator sections being closed to each other while the condensers sections are spaced from each other.

6. The heat dissipation device as described in claim 1, wherein each of the second fin assemblies comprises an elongated base, the second fins extending upwardly from the base.

7. A heat dissipation device comprising:
a heat sink comprising a first fin assembly and two second fin assemblies, the first fin assembly comprising a plurality of first fins and a plurality of heat dissipation vanes each having a smaller size than the first fins, each of the first fins and the heat dissipation vanes arranged along a first direction of the heat sink, a first airflow channel being defined between each two neighboring first fins and heat dissipation vanes, the heat dissipation vanes arranged on two opposite sides of the first fins and cooperating with the first fins to define two receiving rooms on the two opposite sides of the first fins respectively, the second fin assemblies being received in the receiving rooms of the first fin assembly, each of the second fin assemblies comprising a plurality of second fins each arranged along a second direction of the heat sink, the second direction being different from the first direction, a second airflow channel being defined between each two neighboring second fins; and
a fan mounted on the heat sink for generating an airflow through the first airflow channels and the second airflow channels.

8. The heat dissipation device as described in claim 7, further comprising two heat pipes, each of the heat pipes comprising a condenser section and an evaporation section, two through holes being defined in the first fin assembly for receiving the condenser sections of the heat pipes therein respectively, the evaporation sections thermally contacting with a bottom side of the heat sink.

9. The heat dissipation device as described in claim 8, wherein a groove is defined in the bottom side of the heat sink for receiving the evaporation sections of the heat pipes therein side by side.

10. The heat dissipation device as described in claim 8, wherein the evaporation sections are parallel and close to each other, and the condenser sections are parallel to and spaced from each other.

11. The heat dissipation device as described in claim 7, wherein each of the first airflow channels and the second airflow channels communicate with a top side of the heat sink, the first fins being perpendicular to the second fins with the first airflow channels and the second airflow channels communicated with four sides of the heat sink respectively.

12. The heat dissipation device as described in claim 11, wherein each of the second fin assembly comprises an elongated base, the second fins extending upwardly from the base.

13. A heat dissipation device comprising:
a first fin assembly having a plurality of first fins extending along a first direction, the first fins defining at least a recess in one of four lateral sides thereof, and
a second fin assembly having a plurality of second fins extending along a second direction, the second fin assembly being received in the recess, the second direction being different from the first direction, passages between the first fins and the second fins being communicated with a common top side of the first and second fin assemblies, a common bottom side of the of the first and second fin assemblies being adapted for thermally connecting with an electronic component.

14. The heat dissipation device as described in claim 13, further comprising a fan mounted on the common top side.

15. The heat dissipation device as described in claim 13, wherein the first direction is perpendicular to the second direction.

16. The heat dissipation device as described in claim 14, wherein the first direction is perpendicular to the second direction.

17. The heat dissipation device as described in claim 16, further comprising a heat pipe having an evaporator section at the common bottom side and a condensing section extending through the first fin assembly.
